(19) United States
(12) Patent Application Publication
(10) Pub. No.: US 2014/0055437 A1
(43) Pub. Date: Feb. 27, 2014

(54) DIGITAL-TO-ANALOG CONVERTER, DISPLAY DRIVING CIRCUIT HAVING THE SAME, AND DISPLAY APPARATUS HAVING THE SAME

(71) Applicant: SAMSUNG DISPLAY CO., LTD., Yongin-City (KR)

(72) Inventors: Young-Il BAN, Hwaseong-si (KR); SUNKYU SON, Suwon-si (KR); Kyungha KIM, Hwaseong-si (KR)

(73) Assignee: SAMSUNG DISPLAY CO., LTD., Yongin-City (KR)

(21) Appl. No.: 13/738,496

(22) Filed: Jan. 10, 2013

(30) Foreign Application Priority Data
Aug. 21, 2012 (KR) 10-2012-0091487

(51) Int. Cl. H03M 1/66; G09G 5/00

(52) U.S. Cl. CPC H03M 1/66; G09G 5/001
USPC 345/211; 341/137

(57) ABSTRACT

A display apparatus includes pixels, gate lines and data lines, a gate driver driving the gate lines, a data driver which drives the data lines, and a timing controller which controls the gate and data drivers and provides digital image signals to the data driver. The data driver includes a digital-to-analog converter which receives first and second gamma voltages and converting the digital image signals to analog image signals and an output buffer which outputs the analog image signals to the data lines. The digital-to-analog converter includes a resistor string which receives the first and second gamma voltages and generates gamma voltages, a look-up table which stores selection signals, a first decoder which selects the gamma voltages and outputs the selected gamma voltages as gamma reference voltages, and a second decoder which converts the digital image signals to the analog image signals based on the gamma reference voltages.

This application claims priority to Korean Patent Application No. 10-2012-0091 487, filed on Aug. 21, 2012, and all the benefits accruing therefrom under 35 U.S.C. §119, the content of which in its entirety is herein incorporated by reference.

### BACKGROUND

1. Field

The disclosure relates to a digital-to-analog converter, a display driving circuit including the digital-to-analog converter, and a display apparatus including the display driving circuit.

2. Description of the Related Art

Human eyes have a non-linear sensitivity to brightness. That is, human eyes are sensitive to variations under a black and white scale. Therefore, a correction process of correcting brightness of an image displayed on a display panel is required to allow brightness of an image signal from an external source to correspond to brightness of an image displayed on a display panel.

A digital image signal from the external source is converted to an analog voltage by a digital-to-analog converter. In general, the digital-to-analog converter is designed to be non-linearly operated using various reference voltages of reference voltage tap points. That is, the digital-to-analog converter converts the digital image signal to the analog voltage having a corresponding gamma characteristic by differently setting voltage differences between the reference voltages.

In recent years, a linear digital-to-analog converter having an increased bit width, e.g., increased by two or three bits, has been researched to obtain a desired gamma characteristic, which may causes an increase in the circuit area of the digital-to-analog converter.

### SUMMARY

The disclosure provides a digital-to-analog converter with reduced circuit area.

The disclosure provides a display driving circuit having the digital-to-analog converter.

The disclosure provides a display apparatus having the display driving circuit provided with the digital-to-analog converter.

Exemplary embodiments of the invention provide a digital-to-analog converter including a resistor string that generates a plurality of gamma voltages, a look-up table that stores a plurality of selection signals, a first decoder that selects the gamma voltages in response to the selection signals and outputs the selected gamma voltages as a plurality of gamma reference voltages, and a second decoder that converts a plurality of digital image signals to a plurality of analog image signals based on the gamma reference voltages.

In an exemplary embodiment, the first decoder may include a plurality of selectors, and each of the selectors may receive the gamma voltages and output one of the gamma voltages as a corresponding gamma reference voltage of the gamma reference voltages in response to a corresponding selection signal of the selection signals.

In an exemplary embodiment, the selection signals stored in the look-up table may include gamma voltage information to be selected by each of the selectors.

In an exemplary embodiment, a number of the selectors may be 2×r (r is a natural number) when each of the digital image signals has an r-bit data.

In an exemplary embodiment, the second decoder may include a plurality of decoders, and each of the decoders may receive the gamma reference voltages and output one of the gamma reference voltages as a corresponding analog image signal of the analog image signals in response to a corresponding digital image signal of the digital image signals.

In an exemplary embodiment, the resistor string may include a plurality of resistors connected to each other in series between a first gamma voltage and a second gamma voltage, and the resistor string may output voltages at connection nodes between the resistors as the gamma voltages.

In an exemplary embodiment, a number of the resistors may be 2^{(r+α)} (each of r and α is a natural number) when each of the digital image signals has an r-bit.

In an exemplary embodiment, a resistance of each of the resistors may be set to allow voltage differences between adjacent gamma voltages among the gamma voltages to be substantially equal to each other.

In another exemplary embodiment of the invention, a display driving circuit includes a digital-to-analog converter that receives a first gamma voltage and a second gamma voltage and converts a plurality of digital image signals to a plurality of analog image signals, and an output buffer that outputs the analog image signals to a plurality of data lines in response to a line latch signal. In such an embodiment, the digital-to-analog converter includes a resistor string that receives the first and second gamma voltages and generates a plurality of gamma voltages, a look-up table that stores a plurality of selection signals, a first decoder that selects the gamma voltages in response to the selection signals and outputs the selected gamma voltages as a plurality of gamma reference voltages, and a second decoder that converts a plurality of digital image signals to a plurality of analog image signals based on the gamma reference voltages.

In an exemplary embodiment, the first decoder may include a plurality of selectors, each of the selectors may receive the gamma voltages and output one of the gamma voltages as a corresponding gamma reference voltage of the gamma reference voltages in response to a corresponding selection signal of the selection signals, and the selection signals stored in the look-up table may include gamma voltage information to be selected by each of the selectors.

In an exemplary embodiment, the second decoder may include a plurality of decoders, and each of the decoders may receive the gamma reference voltages and output one of the gamma reference voltages as a corresponding analog image signal of the analog image signals in response to a corresponding digital image signal of the digital image signals.

In an exemplary embodiment, the resistor string may include a plurality of resistors connected to each other in series between a first gamma voltage and a second gamma voltage, and the resistor string may output voltages at connection nodes between the resistors as the gamma voltages.

In an exemplary embodiment, a resistance of each of the resistors may be set to allow voltage differences between adjacent gamma voltages among the gamma voltages to be substantially equal to each other.

Another exemplary embodiment of the invention, a display apparatus includes a plurality of pixels arranged in areas and connected to a plurality of gate lines and a plurality of data lines crossing the gate lines, a gate driver that drives the gate lines, a data driver that drives the data lines, and a timing controller that controls the gate driver and the data driver in response to image signals and control signals from an external source and provides a plurality of digital image signals to the data driver. The data driver includes a digital-to-analog converter that receives a first gamma voltage and a second gamma voltage and converts the digital image signals to a plurality of analog image signals and an output buffer that outputs the analog image signals to data lines in response to a line latch signal. The digital-to-analog converter includes a resistor string that receives the first and second gamma voltages and generates a plurality of gamma voltages, a look-up table that stores a plurality of selection signals, a first decoder that selects the gamma voltages in response to the selection signals and outputs the selected gamma voltages as a plurality of gamma reference voltages, and a second decoder that converts the digital image signals to the analog image signals based on the gamma reference voltages.

In an exemplary embodiment, the first decoder may include a plurality of selectors, each of the selectors may receive the gamma voltages and output one of the gamma voltages as a corresponding gamma reference voltage of the gamma reference voltages in response to a corresponding selection signal of the selection signals, and the selection signals stored in the look-up table may include gamma voltage information selected by each of the selectors.

In an exemplary embodiment, the timing controller may apply the selection signals to the data driver as the digital image signals during a vertical blank period in which effective digital image signals are not output, and the data driver may store the selection signals from the timing controller in the look-up table.

In an exemplary embodiment, the data driver may receive the selection signals through an inter-integrated circuit bus, and the selection signals provided through the inter-integrated circuit bus may be stored in the look-up table.

In an exemplary embodiment, the second decoder may include a plurality of decoders, and each of the decoders may receive the gamma reference voltages and output any one of the gamma reference voltages as a corresponding analog image signal of the analog image signals in response to a corresponding digital image signal of the digital image signals.

In an exemplary embodiment, the resistor string may include a plurality of resistors connected to each other in series between the first gamma voltage and the second gamma voltage, the resistor string outputs voltages at connection nodes between the resistors as the gamma voltages, and a resistance of each of the resistors may be set to allow voltage differences between adjacent gamma voltages among the gamma voltages to be substantially equal to each other.

According to exemplary embodiments, the circuit area of the linear digital-to-analog converter is substantially reduced, and the circuit area of the display driving circuit and the display apparatus, which include the linear digital-to-analog converter, is thereby substantially minimized.

### BRIEF DESCRIPTION OF THE DRAWINGS

The above and other features of the invention will become readily apparent by reference to the following detailed description when considered in conjunction with the accompanying drawings wherein:

FIG. 1 is a block diagram illustrating an exemplary embodiment of a display apparatus according to the invention;

FIG. 2 is a block diagram illustrating an exemplary embodiment of a data driver shown in FIG. 1;

FIG. 3 is a block diagram illustrating an exemplary embodiment of a digital-to-analog converter shown in FIG. 2;

FIG. 4 is a block diagram showing an exemplary embodiment of a resistor string, first decoder and the second decoder of the digital-to-analog converter shown in FIG. 3;

FIG. 5 is a conceptual diagram illustrating an exemplary embodiment of selection information stored in a look-up table shown in FIG. 4;

FIG. 6 is a conceptual diagram illustrating a digital image signal of one frame, which is provided to the data driver from the timing controller shown in FIG. 1;

FIG. 7 is a signal timing diagram illustrating a digital image signal of one frame in a normal mode;

FIG. 8 is a signal timing diagram illustrating a digital image signal of one frame in a data transmission mode of the look-up table;

FIG. 9 is a block diagram illustrating an alternative exemplary embodiment of a display apparatus according to the invention; and

FIG. 10 is a block diagram illustrating an exemplary embodiment of a display system according to the invention.

### DETAILED DESCRIPTION

The invention will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims set forth herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, exemplary embodiments of the invention will be explained in detail with reference to the accompanying drawings.

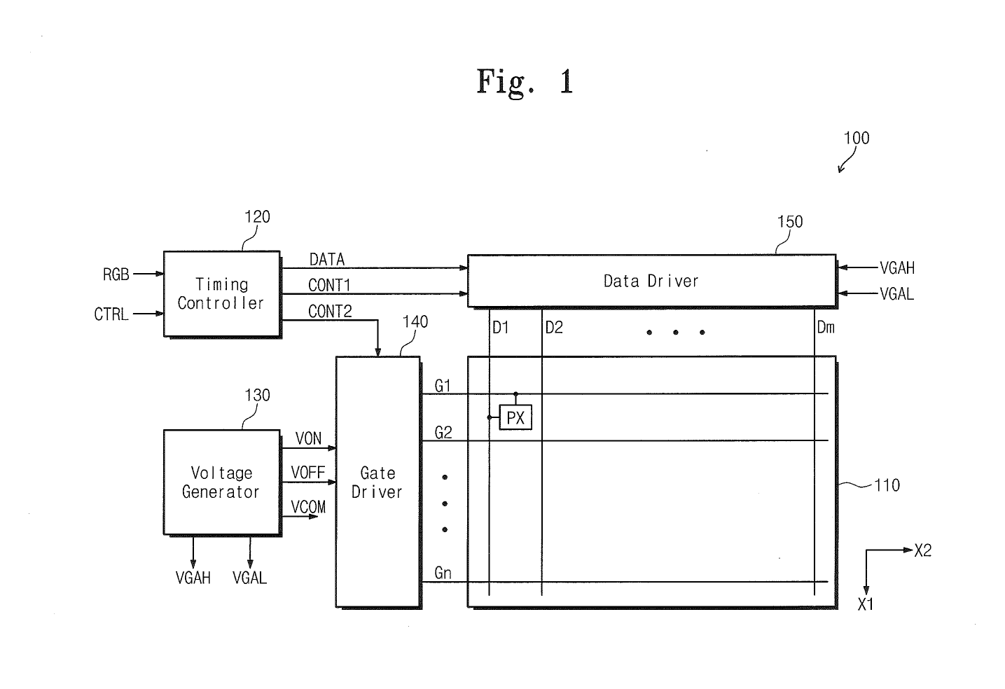

FIG. 1 is a block diagram illustrating an exemplary embodiment of a display apparatus according to the invention. Hereinafter, an exemplary embodiment, where the display apparatus is a liquid crystal display, will be described, but the invention is not limited to the liquid crystal display.

Referring to FIG. 1, a display apparatus 100 includes a display panel 110, a timing controller 120, a voltage generator 130, a gate driver 140 and a data driver 150.

The display panel 110 includes a plurality of data lines D1 to Dm that extends in a first direction X1, a plurality of gate lines G1 to Gn that extends in a second direction X2 to cross the data lines D1 to Dm, and a plurality of pixels PX arranged substantially in a matrix form including rows by columns. The pixels are connected to the data lines D1 to Dm and the gate lines G1 to Gn. The data lines D1 to Dm are insulated from the gate lines G1 to Gn.

Although not shown in FIG. 1, each pixel PX may include a switching transistor connected to a corresponding data line of the data lines D1 to Dm and a corresponding gate line of the gate lines G1 to Gn, a liquid crystal capacitor connected to the switching transistor, and a storage capacitor connected to the switching transistor.

The timing controller 120 receives image signals RGB and control signals CTRL, e.g., a vertical synchronization signal, a horizontal synchronization signal, a main clock signal, a data enable signal, etc., which are used to control the image signals RGB from an external source (not shown). The timing controller 120 converts the image signals RGB to digital image signals DATA appropriate to an operation condition of the display panel 110 on based on the control signals CTRL. The timing controller 120 applies the digital image signals DATA and a first control signal CONT1 to the data driver 150 and applies a second control signal CONT2 to the gate driver 140. The first control signal CONT1 includes a first start pulse signal, a clock signal, a polarity inversion signal and a line latch signal, and the second control signal CONT2 includes a vertical synchronization signal, an output enable signal and a gate pulse signal.

The voltage generator 130 generates a gate-on voltage VON, a gate-off voltage VOFF, and a common voltage VCOM, which are used to drive the display panel 110. The voltage generator 130 generates a first gamma voltage VGAH and a second gamma voltage VGAL, which are used to drive the data driver 150.

The gate driver 140 drives the gate lines G1 to Gn in response to the second control signal CONT2 from the timing controller 120, and to the gate on voltage VON and the gate off voltage VOFF from the voltage generator 130. The gate driver 140 includes a gate driver integrated circuit (“IC”), but not being limited thereto. In exemplary embodiments, the gate driver 140 may be configured in a circuit using oxide semiconductor, amorphous semiconductor, crystalline semiconductor or polycrystalline semiconductor, for example.

The data driver 150 outputs gray scale voltages using the first gamma voltage VGAH and the second gamma voltage VGAL to drive the data lines D1 to Dm in response to the digital image signals DATA and the first control signal CONT1.

When the gate-on voltage VON is applied to one gate line by the gate driver 140, switching transistors arranged in a corresponding row and connected to the one gate line are turned on. In such an embodiment, the data driver 150 provides the gray scale voltages corresponding to the digital image signals DATA to the data lines D1 to Dm. The gray scale voltages applied to the data lines D1 to Dm are applied to corresponding liquid crystal capacitors and corresponding storage capacitors through the turned-on switching transistors. A period, in which the switching transistors arranged in one row are turned on, is referred to as “one horizontal period” or “1H.”

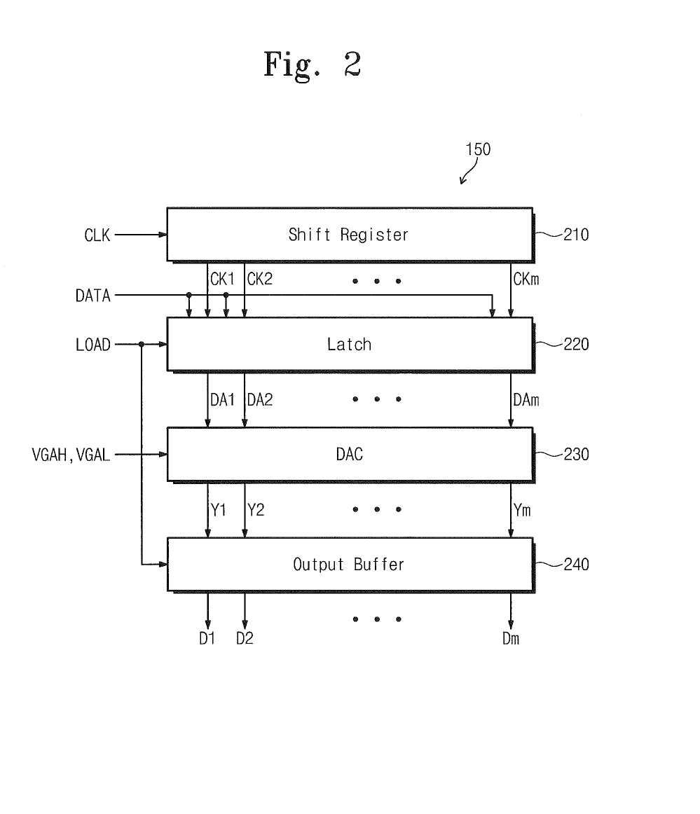

FIG. 2 is a block diagram illustrating an exemplary embodiment of the data driver shown in FIG. 1.

Referring to FIG. 2, the data driver 150 includes a shift register 210, a latch 220, a digital-to-analog converter (“DAC”) 230 and an output buffer 240.

In FIG. 2, the shift register 210 receives a clock signal CLK, which is included in the first control signal CONT1 from the timing controller 120 shown in FIG. 1.

The shift register 210 sequentially activates latch clock signals CK1 to CKm in synchronization with the clock signal CLK. The latch 220 latches the digital image signals DATA in synchronization with the latch clock signals CK1 to CKm and simultaneously applies latch digital image signals DA1 to DAm to the DAC 230 in response to a line latch signal LOAD, which is included in the first control signal CONT1 from the timing controller 120 shown in FIG. 1.

The DAC 230 receives the first gamma voltage VGAH and the second gamma voltage VGAL from the voltage generator 130 shown in FIG. 1 and outputs analog image signals Y1 to Ym. The output buffer 240 outputs the analog image signals Y1 to Ym from the DAC 230 to the data lines D1 to Dm in response to the line latch signal LOAD.

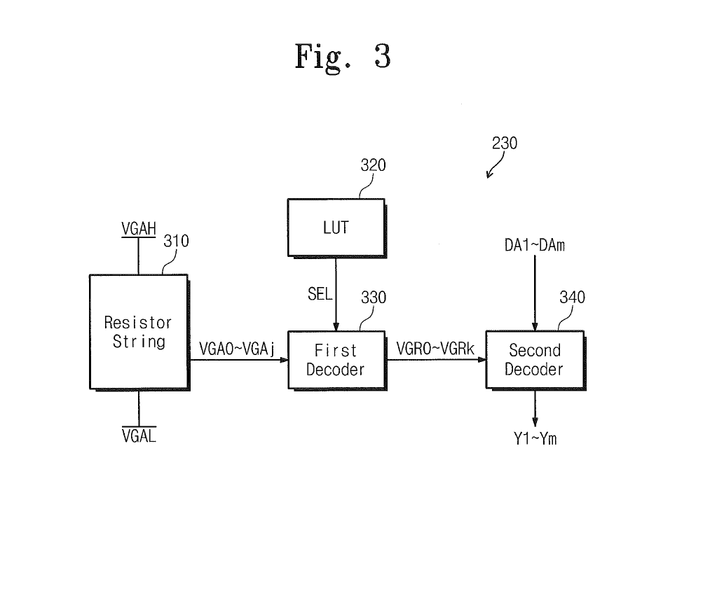

FIG. 3 is a block diagram illustrating an exemplary embodiment of the DAC shown in FIG. 2.

Referring to FIG. 3, the DAC 230 includes a resistor string 310, a look-up table 320 (also referred to as “LUT”), a first decoder 330 and a second decoder 340.

The resistor string 310 receives the first gamma voltage VGAH and the second gamma voltage VGAL from the voltage generator 130 illustrated in FIG. 1 and generates a plurality of gamma voltages VGA0 to VGAj.

The look-up table 320 stores a selection signal SEL to select a portion of the plurality of gamma voltages VGA0 to VGAj. The first decoder 330 selects the portion of the gamma voltages VGA0 to VGAj based on the selection signal SEL stored in the look-up table 320 and output the selected gamma voltages as the gamma reference voltages VGR0 to VGRk. Here, each of “j and “k” is a natural number and “j” is greater than “k” (i.e., j>k). The second decoder 340 converts the digital image signals DA1 to DAm to the analog image signals Y1 to Ym based on the gamma reference voltages VGR0 to VGRk.

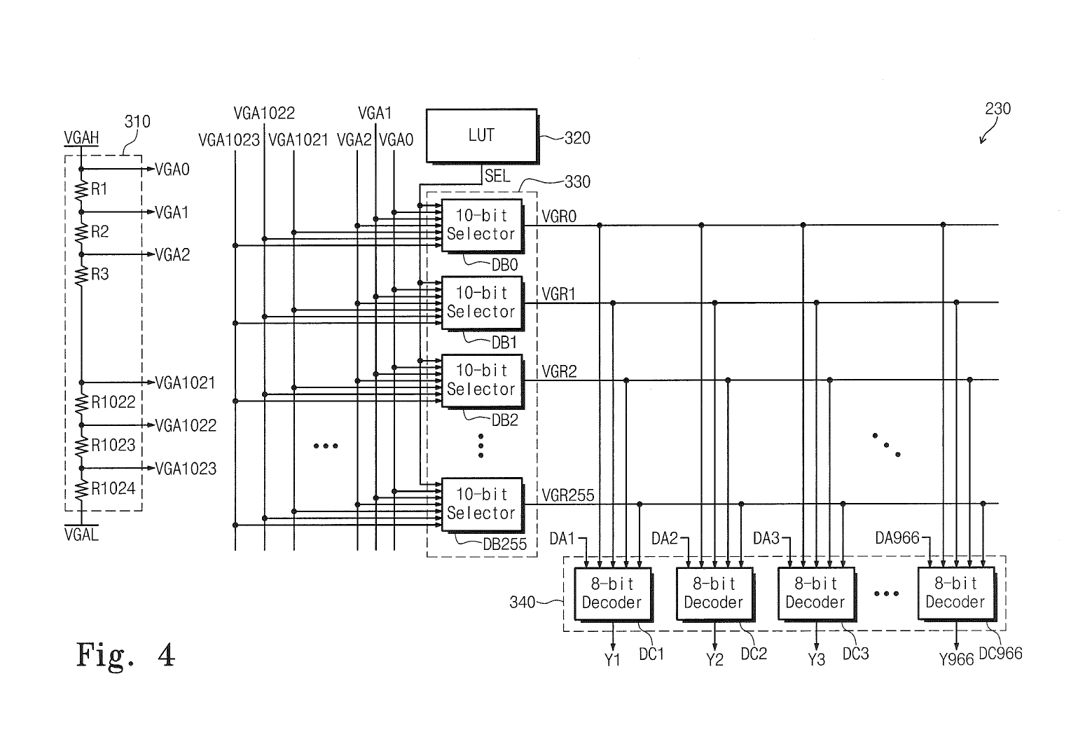

FIG. 4 is a block diagram showing an exemplary embodiment of the resistor string 310, the look-up table 320, the first decoder 330 and the second decoder 340 of the digital-to-analog converter shown in FIG. 3. In one exemplary embodiment, for example, as shown in FIG. 4, the DAC 230 has 966 output channels and each of the digital image signals DA1 to DAm is represented by 8-bit. In such an embodiment, the number of the gamma voltages VGA0 to VGAj output from the resistor string 310 is 1024.

Referring to FIG. 4, the resistor string 310 includes 1024 resistors R1 to R1024 sequentially connected to each other in series between the first gamma voltage VGAH and the second gamma voltage VGAL from the voltage generator 130. Voltages at nodes between the first gamma voltage VGAH and each of the resistors R1 to R1024 are output as the gamma voltages VGA0 to VGA1023. A resistance of each of the resistors R1 to R1024 is set to allow voltage differences between adjacent gamma voltages among the gamma voltages VGA0 to VGA1023 to be substantially equal to each other. In an exemplary embodiment, where each of the digital image signal DA1 to D966 is represented by 8-bit, the resistor string 310 includes at least 1024 resistors R1 to R1024. In an alternative exemplary embodiment, the resistor string 310 may include more than 1023 resistors, e.g., at least 2048 or more resistors.

The look-up table 320 stores the selection signal SEL to select the portion of the gamma voltages VGA0 to VGA1023. In one exemplary embodiment, for example, the first decoder 330 includes 256 selectors DB0 to DB255. Each of the selectors DB0 to DB255 receives the gamma voltages VGA0 to VGA1023 and outputs one of the gamma voltages VGA0 to VGA1023 as one of the gamma reference voltages VGR0 to VGR255 in accordance with the selection signal SEL from the look-up table 320. In one exemplary embodiment, for example, a first selector DB0 receives the gamma voltages VGA0 to VGA1023 and outputs one of the gamma voltages VGA0 to VGA1023 as the gamma reference voltages VGR0 based on the selection signal SEL from the look-up table 320. A second selector DB1 receives the gamma voltages VGA0 to VGA1023 and outputs one of the gamma voltages VGA0 to VGA1023 as the gamma reference voltages VGR1 based on the selection signal SEL from the look-up table 320. A 266^{th} selector DB255 receives the gamma voltages VGA0 to VGA1023 and outputs one of the gamma voltages VGA0 to VGA1023 as the gamma reference voltages VGR255 based on the selection signal SEL from the look-up table 320. The selection signal SEL stored in the look-up table 320 includes gamma voltage information corresponding to the selectors DB0 to DB255.

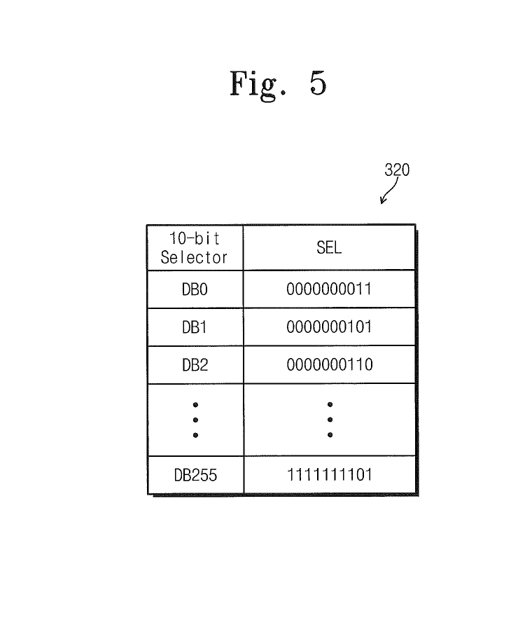

FIG. 5 is a conceptual diagram illustrating an exemplary embodiment of selection information stored in the look-up table shown in FIG. 4.

Referring to FIGS. 4 and 5, the look-up table 320 stores the selection signal SEL corresponding to each of the selectors DB0 to DB255. In one exemplary embodiment, for example, the first selector DB0 outputs the gamma voltage VGA3 as the gamma reference voltage VGR0 in response to the selection signal SEL corresponding thereto, e.g., 0000000011, and the second selector DB1 outputs the gamma voltage VGA4 as the gamma reference voltage VGR1 in response to the selection signal SEL corresponding thereto, e.g., 0000000101. As described above, each of the selectors DB0 to DB255 is operated as the 10-bit selector to select any one of 1024 gamma voltages VGA0 to VGA1023.

Referring back to FIG. 4, the second decoder 340 includes 966 decoders DC1 to DC966 respectively corresponding to the output channels of the DAC 230. The decoders DC1 to DC966 convert the digital image signals DA1 to DA966 to the analog image signals Y1 to Y966 based on the gamma reference voltages VGR0 to VGR255 output from the 10-bit selectors DB0 to DB255. In one exemplary embodiment, for example, a first decoder DC1 outputs any one of the gamma reference voltages VGR0 to VGR255, which corresponds to a first digital image signal DA1, as a first analog image signal Y1. A second decoder DC2 outputs any one of the gamma reference voltages VGR0 to VGR255, which corresponds to a second digital image signal DA2, as a second analog image signal Y2. A 966th decoder DC966 outputs any one of the gamma reference voltages VGR0 to VGR255, which corresponds to a 966th digital image signal DA966, as a 966th analog image signal Y966. As described above, each of the decoders DC1 to DC966 operates as an 8-bit decoder, and thus each of the 8-bit decoders DC1 to DC966 converts the 8-bit digital image signals DA1 to DA966 to the analog image signals Y1 to Y966 based on the 256 gamma reference voltages VGR0 to VGR255. Therefore, each of the 8-bit decoders DC1 to DC966 includes a switching circuit to select one of the 256 gamma reference voltages VGR0 to VGR255.

A bit width of the linear DAC may be increased, e.g., increased by two or three bits, to obtain a predetermined gamma characteristic. When each of the digital image signals DA1 to DA966 is represented by 8-bit, the resistor string 310 may include at least 1024 (2¹⁰) resistors R1 to R1024, or the resistor string 310 may include at least 2048 (2¹¹) or more resistors to increase the bit width of the linear DAC, such that a circuit area provided for the switching circuit used to select any one of the 1024 gamma voltages VGA0 to VGA1023 generated by the 1024 resistors R1 to R1024 is substantially greater than a circuit area of a non-linear DAC.

As shown in FIG. 4, in an exemplary embodiment, the 1024 gamma voltages VGA0 to VGA1023 are selected to the 256 gamma reference voltages VGR0 to VGR255 by the 10-bit selectors DB0 to DB255. Thus, in such an embodiment, the 8-bit decoder may be used as each of the decoders DC1 to DC966, such that the circuit area of each of the decoders DC1 to DC966 is substantially reduced.

Among elements of the data driver 150 shown in FIG. 2, the circuit area of the DAC 230 may occupy about 60% of the total circuit area of the data driver 150. When each of the decoders DC1 to DC966 is realized by the 8-bit decoder, the circuit area of the data driver 150 is substantially reduced by nearly two-third.

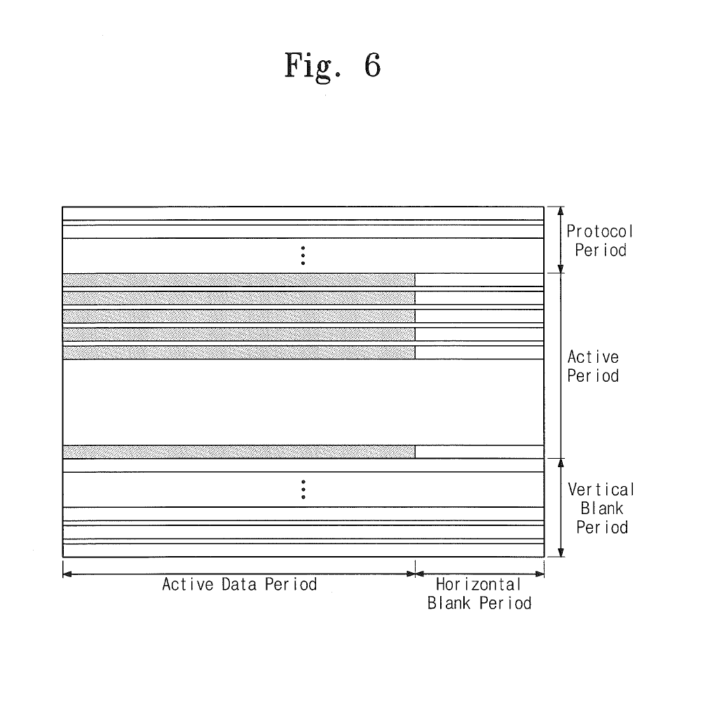

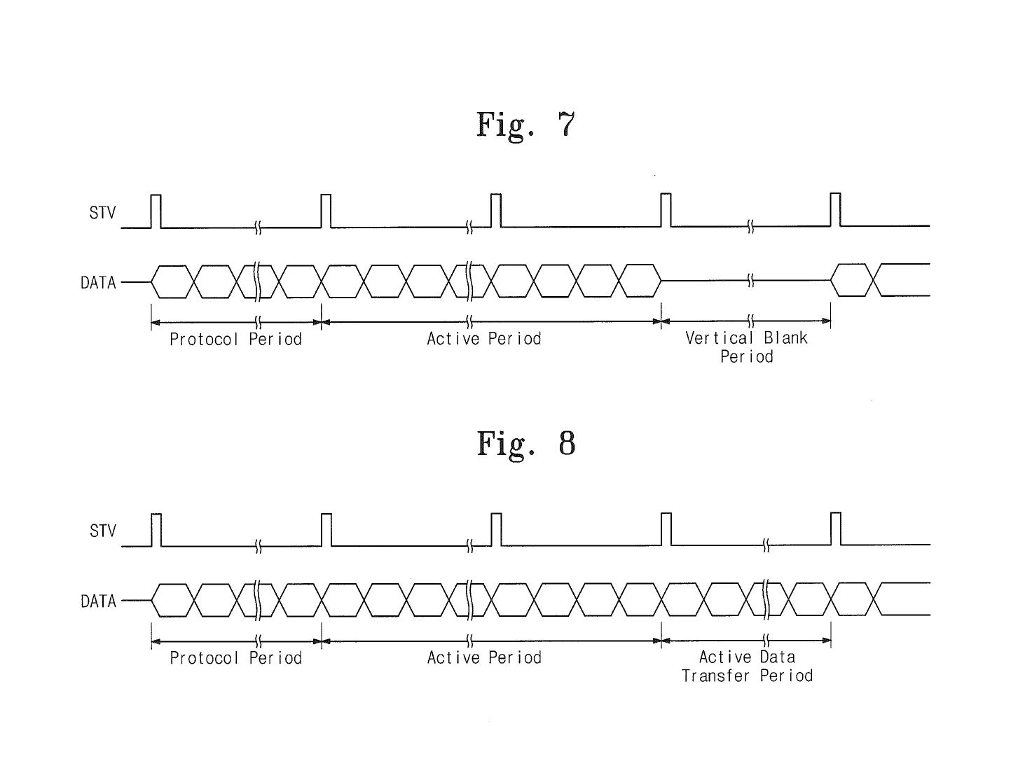

FIG. 6 is a conceptual diagram illustrating an exemplary embodiment of a digital image signal of one frame, which is provided to the data driver from the timing controller shown in FIG. 1. FIG. 7 is a timing diagram illustrating a digital image signal of one frame in a normal mode, and FIG. 8 is a signal timing diagram illustrating a digital image signal of one frame in a data transmission mode of the look-up table.

Referring to FIGS. 6 and 7, the digital image signal DATA of the one frame, which is provided to the data driver 150 from the timing controller 120 shown in FIG. 1, includes a protocol period, an active period, active data period, a horizontal blank period and a vertical blank period. The timing controller 120 provides effective digital image signal DATA to the data driver 150 during the active period. The effective digital image signal DATA is the image signal displayed on the display panel 110. The digital image signal DATA of the one frame includes the predetermined vertical blank period.

In the normal mode, the timing controller 120 does not provide the digital image signal DATA to the data driver 150 or the digital image signal DATA at the level of the common voltage VCOM during the vertical blank period.

In the transmission mode of the look-up table, the timing controller 120 transmits the selection signal SEL stored in the look-up table 320 of the data driver 150 during the vertical blank period of the digital image signal DATA. The period during which the selection signal SEL is transmitted is referred to as “active data transfer period.” Therefore, a user or manufacturer may change the selection signal SEL in the look-up table 320 to obtain a predetermined gamma characteristic.

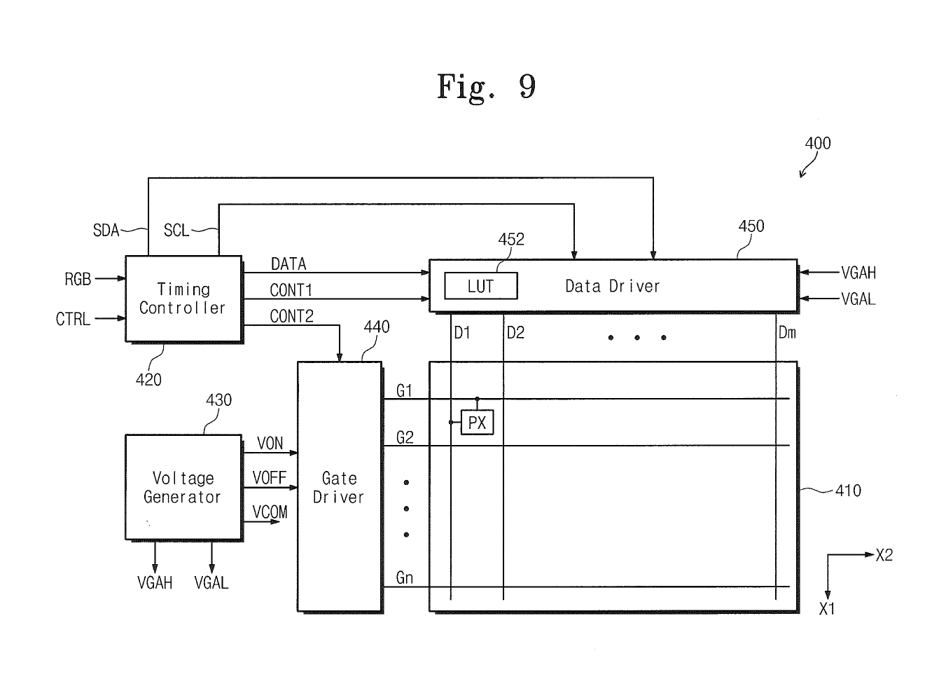

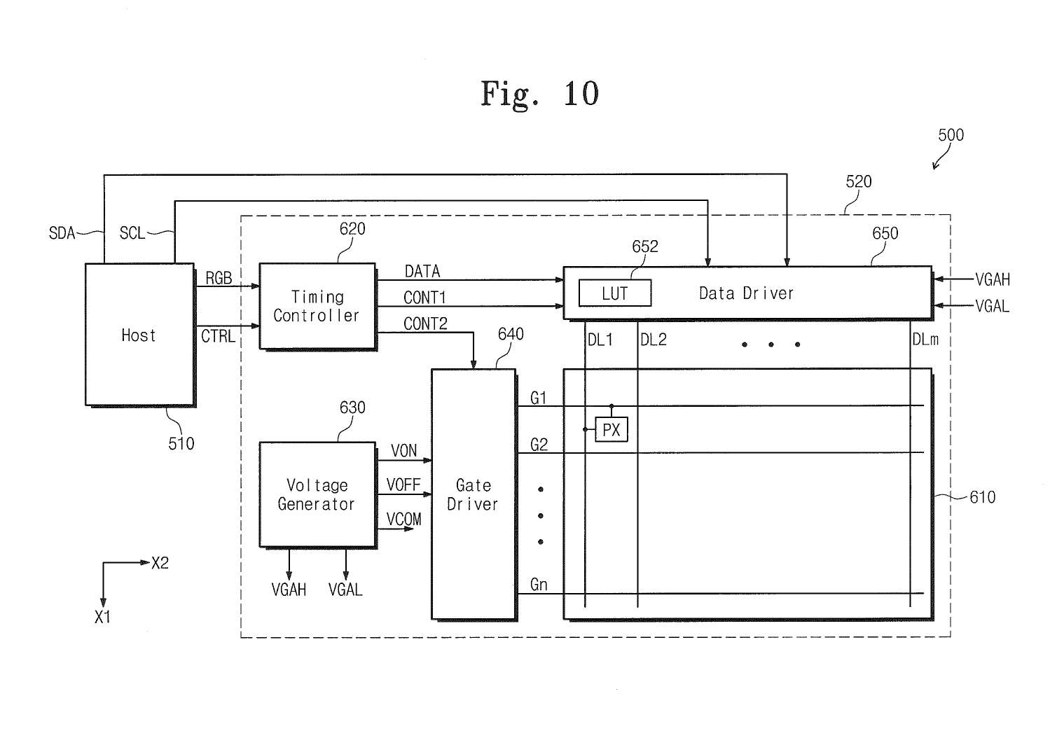

FIG. 9 illustrates a block diagram illustrating an alternative exemplary embodiment of a display apparatus according to the invention.

In an exemplary embodiment, as shown in FIG. 9, a display apparatus 400 includes a display panel 410, a timing controller 420, a voltage generator 430, a gate driver 440 and a data driver 450. The display apparatus 400 of FIG. 9 is substantially the same as the display apparatus 100 shown in FIG. 1 except that the timing controller 420 and the data driver 450 are connected to each other by an inter-integrated circuit (“I²C”) bus SCL and SDA. In the transmission mode of the look-up table, the timing controller 420 transmits the selection signal SEL to be stored in a look-up table 452 of the data driver 450 through the I²C bus SCL and SDA. Thus, the user or manufacturer of manufacturing the display apparatus 400 may change the selection signal SEL in the look-up table 452 to obtain a predetermined gamma characteristic.

FIG. 10 illustrates a block diagram illustrating an exemplary embodiment of a display system according to the invention.

Referring to FIG. 10, a display system 500 includes a host 510 and a display apparatus 520. In such an embodiment, as shown in FIG. 9, the display apparatus 520 includes a display panel 610, a timing controller 620, a voltage generator 630, a gate driver 640 and a data driver 650. The display apparatus 520 may be substantially the same as the display apparatus 100 shown in FIG. 1. The host 510 applies image signals RGB and control signals CTRL used to control the image signals RGB, e.g., a vertical synchronization signal, a horizontal synchronization signal, a main clock signal MCLK, a data enable signal DE, etc., to the display apparatus 520.

The host 510 is connected to the data driver 650 of the display apparatus 520 by an I²C bus SCL and SDA. In the transmission mode of the look-up table, the host 510 transmits the selection signal SEL to be stored in a look-up table 652 of the data driver 650 through the I²C bus SCL and SDA. Accordingly, the user or manufacturer of manufacturing the display apparatus 520 may change the selection signal SEL in the look-up table 652 to obtain a predetermined gamma characteristic.

As described above, the selection information to be stored in the look-up table of the data driver is transmitted to the data driver using the (I²C bus, but it should not be limited thereto or thereby.

Although the exemplary embodiments of the invention have been described, it is understood that the invention should not be limited to these exemplary embodiment but various changes and modifications can be made by one ordinary skilled in the art within the spirit and scope of the invention as hereinafter claimed.

What is claimed is:

1. A digital-to-analog converter comprising:
a resistor string which generates a plurality of gamma voltages;
a look-up table which stores a plurality of selection signals;
a first decoder which selects the gamma voltages in response to the selection signals and outputs the selected gamma voltages as a plurality of gamma reference voltages; and
a second decoder which converts a plurality of digital image signals to a plurality of analog image signals based on the gamma reference voltages from the first decoder.

2. The digital-to-analog converter of claim 1, wherein
the first decoder comprises a plurality of selectors, and
each of the selectors receives the gamma voltages and outputs one of the gamma voltages as a corresponding gamma reference voltage of the gamma reference voltages in response to a corresponding selection signal of the selection signals.

3. The digital-to-analog converter of claim 2, wherein
the selection signals stored in the look-up table comprise gamma voltage information to be selected by each of the selectors.

4. The digital-to-analog converter of claim 2, wherein a number of the selectors is 2×r when each of the digital image signals has an r-bit data, wherein r is a natural number.

5. The digital-to-analog converter of claim 1, wherein
the second decoder comprises a plurality of decoders, and
each of the decoders receives the gamma reference voltages and outputs one of the gamma reference voltages as a corresponding analog image signal of the analog image signals in response to a corresponding digital image signal of the digital image signals.

6. The digital-to-analog converter of claim 1, wherein
the resistor string comprises a plurality of resistors connected to each other in series between a first gamma voltage and a second gamma voltage, and
the resistor string outputs voltages at connection nodes between the resistors as the gamma voltages.

7. The digital-to-analog converter of claim 6, wherein a number of the resistors is 2^{(r+α)} when each of the digital image signals has an r-bit data, wherein each of r and α is a natural number.

8. The digital-to-analog converter of claim 6, wherein a resistance of each of the resistors is set to allow voltage differences between adjacent gamma voltages of the gamma voltages to be substantially equal to each other.

9. A display driving circuit comprising:
a digital-to-analog converter which receives a first gamma voltage and a second gamma voltage and converts a plurality of digital image signals to a plurality of analog image signals; and
an output buffer which outputs the analog image signals to a plurality of data lines in response to a line latch signal,
wherein the digital-to-analog converter comprises:
a resistor string which receives the first and second gamma voltages and generates a plurality of gamma voltages;
a look-up table which stores a plurality of selection signals;
a first decoder which selects the gamma voltages in response to the selection signals and outputs the selected gamma voltages as a plurality of gamma reference voltages; and
a second decoder which converts the digital image signals to the analog image signals based on the gamma reference voltages from the first decoder.

10. The display driving circuit of claim 9, wherein
the first decoder comprises a plurality of selectors,
each of the selectors receives the gamma voltages and outputs one of the gamma voltages as a corresponding gamma reference voltage of the gamma reference voltages in response to a corresponding selection signal of the selection signals, and
the selection signals stored in the look-up table comprise gamma voltage information to be selected by each of the selectors.

11. The display driving circuit of claim 9, wherein
the second decoder comprises a plurality of decoders, and
each of the decoders receives the gamma reference voltages and outputs one of the gamma reference voltages as a corresponding analog image signal of the analog image signals in response to a corresponding digital image signal of the digital image signals.

12. The display driving circuit of claim 9, wherein
the resistor string comprises a plurality of resistors connected to each other in series between a first gamma voltage and a second gamma voltage, and
the resistor string outputs voltages at connection nodes between the resistors as the gamma voltages.

13. The display driving circuit of claim 12, wherein
a resistance of each of the resistors is set to allow voltage differences between adjacent gamma voltages among the gamma voltages to be substantially equal to each other.

14. A display apparatus comprising:
a plurality of pixels connected to a plurality of gate lines and a plurality of data lines crossing the gate lines;
a gate driver which drives the gate lines;
a data driver which drives the data lines; and
a timing controller which controls the gate driver and the data driver in response to image signals and control signals from an external source, and provides a plurality of digital image signals to the data driver,
wherein the data driver comprises:
a digital-to-analog converter which receives a first gamma voltage and a second gamma voltage and converts the digital image signals to a plurality of analog image signals; and
an output buffer which outputs the analog image signals to the data lines in response to a line latch signal,
wherein the digital-to-analog converter comprises:
a resistor string which receives the first and second gamma voltages and generates a plurality of gamma voltages;
a look-up table which stores a plurality of selection signals;
a first decoder which selects the gamma voltages in response to the selection signals and outputs the selected gamma voltages as a plurality of gamma reference voltages; and
a second decoder which converts the digital image signals to the analog image signals based on the gamma reference voltages.

15. The display apparatus of claim 14, wherein
the first decoder comprises a plurality of selectors,
each of the selectors receives the gamma voltages and outputs one of the gamma voltages as a corresponding gamma reference voltage of the gamma reference voltages in response to a corresponding selection signal of the selection signals, and
the selection signals stored in the look-up table comprise gamma voltage information to be selected by each of the selectors.

16. The display apparatus of claim 15, wherein
the timing controller applies the selection signals to the data driver as the digital image signals during a vertical blank period in which effective digital image signals are not output, and
the data driver stores the selection signals from the timing controller in the look-up table.

17. The display apparatus of claim 15, wherein
the data driver receives the selection signals through an inter-integrated circuit bus, and
the selection signals provided through the inter-integrated circuit bus are stored in the look-up table.

18. The display apparatus of claim 14, wherein
the second decoder comprises a plurality of decoders, and
each of the decoders receives the gamma reference voltages and outputs one of the gamma reference voltages as a corresponding analog image signal of the analog image signals in response to a corresponding digital image signal of the digital image signals.

19. The display apparatus of claim 14, wherein
the resistor string comprises a plurality of resistors connected to each other in series between the first gamma voltage and the second gamma voltage,
the resistor string outputs voltages at connection nodes between the resistors as the gamma voltages, and
a resistance of each of the resistors is set to allow voltage differences between adjacent gamma voltages among the gamma voltages to be substantially equal to each other.
